(19) United States
(12) Patent Application Publication
(10) Pub. No.: US 2013/0334603 A1
(43) Pub. Date: Dec. 19, 2013

(54) ISOLATION STRUCTURE FOR SEMICONDUCTOR DEVICES

(71) Applicants: Kangguo CHENG, Schenectady, NY (US); Bruce B. DORIS, Brewster, NY (US); Shom PONOTH, Clifton Park, NY (US); Stefan SCHMITZ, Ballston Spa, NY (US); Raghavasimhan SREENIVASAN, Schenectady, NY (US)

(72) Inventors: Kangguo CHENG, Schenectady, NY (US); Bruce B. DORIS, Brewster, NY (US); Shom PONOTH, Clifton Park, NY (US); Stefan SCHMITZ, Ballston Spa, NY (US); Raghavasimhan SREENIVASAN, Schenectady, NY (US)

(73) Assignee: INTERNATIONAL BUSINESS MACHINES CORPORATION, Armonk, NY (US)

(21) Appl. No.: 13/525,650

(22) Filed: Jun. 18, 2012

(51) Int. Cl. H01L 29/78; H01L 21/302

(52) U.S. Cl. 257/347; 438/435; 257/E21.214; 257/E29.255

(57) ABSTRACT

A method including etching a shallow trench laterally surrounding a portion of a semiconductor substrate, the semiconductor substrate comprising a semiconductor-on-insulator SOI layer, a pad oxide layer, and a pad nitride layer, depositing a first nitride liner, a dielectric liner, and a second nitride liner in the shallow trench, wherein the dielectric liner is located between the first and the second nitride liner, and filling the shallow trench with a shallow trench fill portion.

### BACKGROUND

1. Field of the Invention

The present invention relates generally to semiconductor structures, and more particularly to electrical isolation structures for ultra-thin semiconductor-on-insulator (UTSOI) devices and methods of manufacturing the same.

2. Background of Invention

Ultra-thin semiconductor-on-insulator (UTSOI) devices refer to semiconductor devices formed on an ultra-thin semiconductor-on-insulator (UTSOI) substrate. A UTSOI substrate can be employed to form various semiconductor devices that provide performance advantages through the reduced thickness of the top semiconductor-on-insulator (SOI) layer and the buried oxide layer as compared with conventional SOI substrates.

While UTSOI devices, and especially UTSOI field effect transistors (FETs), are promising candidates for advanced high performance devices, several manufacturing issues need to be resolved before UTSOI devices can be manufactured with high yield. One such issue is erosion of shallow trench isolation structures that are employed to provide lateral electrical isolation between adjacent devices. Specifically, shallow trench isolation structures may experience erosion due to multiple etching steps used to recess various material layers during semiconductor fabrication. The shallow trench isolation structures may be compromised to the point where an electrical short is possible between a subsequently formed contact and a base layer of the UTSOI substrate.

Thus, a method of ensuring sufficient electrical isolation between the base layer of a UTSOI substrate and the contacts despite erosion of the shallow trench isolation structures during semiconductor fabrication is needed to provide functional and reliable UTSOI devices.

### SUMMARY

According to one embodiment of the present invention, a method of forming an isolation structure is provided. The method may include etching a shallow trench laterally surrounding a portion of a semiconductor substrate, the semiconductor substrate comprising a semiconductor-on-insulator SOI layer, a pad oxide layer, and a pad nitride layer. The method may further include, depositing a first nitride liner, a dielectric liner, and a second nitride liner in the shallow trench, wherein the dielectric liner is located between the first and the second nitride liner; and filling the shallow trench with a shallow trench fill portion.

According another exemplary embodiment, an isolation structure is provided. The isolation structure may include a shallow trench laterally surrounding a portion of a semiconductor substrate, the semiconductor substrate comprising a semiconductor-on-insulator SOI layer, a pad oxide layer, and a pad nitride layer. The isolation structure may further include a first nitride liner, a dielectric liner, and a second nitride liner located adjacent to a sidewall and a bottom of the shallow trench, wherein the dielectric liner is located between the first and the second nitride liner, and a shallow trench fill portion configured on top of the second nitride liner.

### BRIEF DESCRIPTION OF THE SEVERAL VIEWS OF THE DRAWINGS

The following detailed description, given by way of example and not intend to limit the invention solely thereto, will best be appreciated in conjunction with the accompanying drawings, in which:

FIGS. 1A-1L illustrate the steps of a method of forming an isolation structure according to one embodiment.

FIG. 1A depicts an SOI substrate used in forming the isolation structure according to an exemplary embodiment.

FIG. 1B depicts a step of forming the isolation structure where a shallow trench may be etched into the SOI substrate according to an exemplary embodiment.

FIG. 1C depicts a step of forming the isolation structure where a stack of shallow trench liners may be deposited within the shallow trench according to an exemplary embodiment.

FIG. 1D depicts a step of forming the isolation structure where a shallow trench fill may be deposited on top of the stack of shallow trench liners according to an exemplary embodiment.

FIG. 1E-1J depict intermediate steps of forming the isolation structure where the shallow trench fill material, the stack of shallow trench liners are recessed according to an exemplary embodiment.

FIG. 1K depicts a step of forming the isolation structure where a gate dielectric layer, a work function metal layer, and a gate material layer may be deposited and subsequently patterned to form a semiconductor device stack according to an exemplary embodiment.

FIG. 1L depicts the final isolation structure where the semiconductor device may be formed according to an exemplary embodiment.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiment set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the presented embodiments.

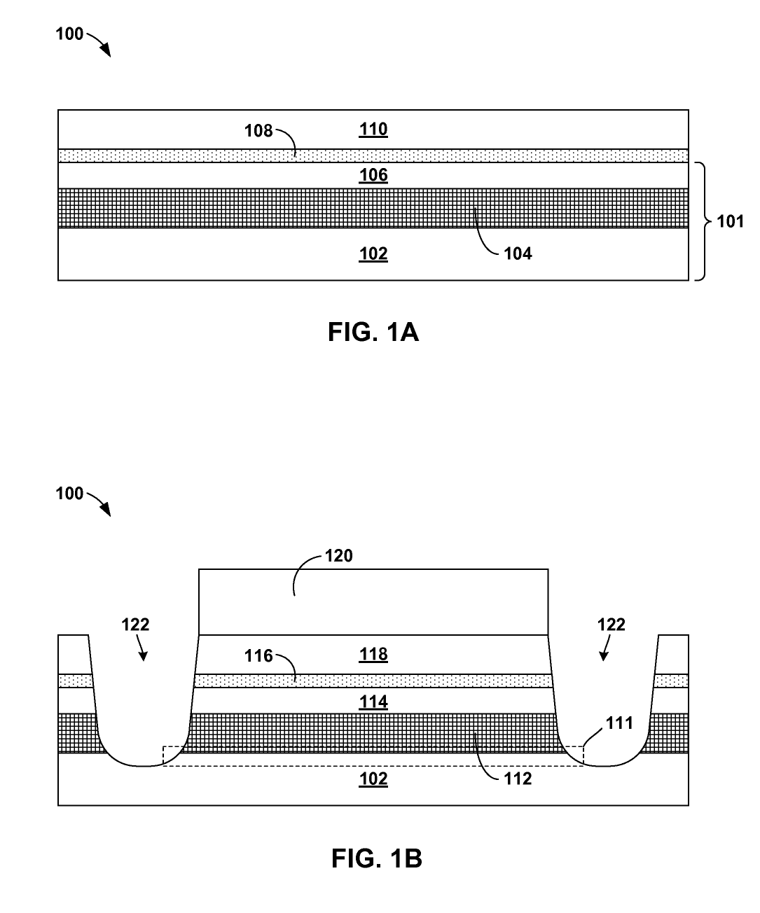

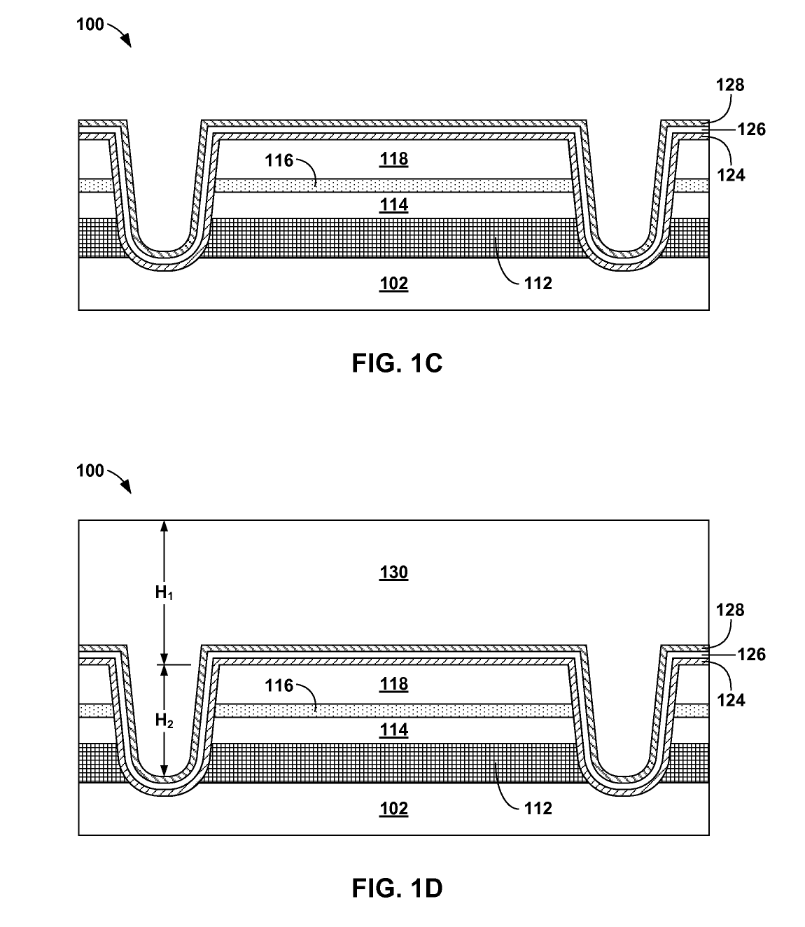

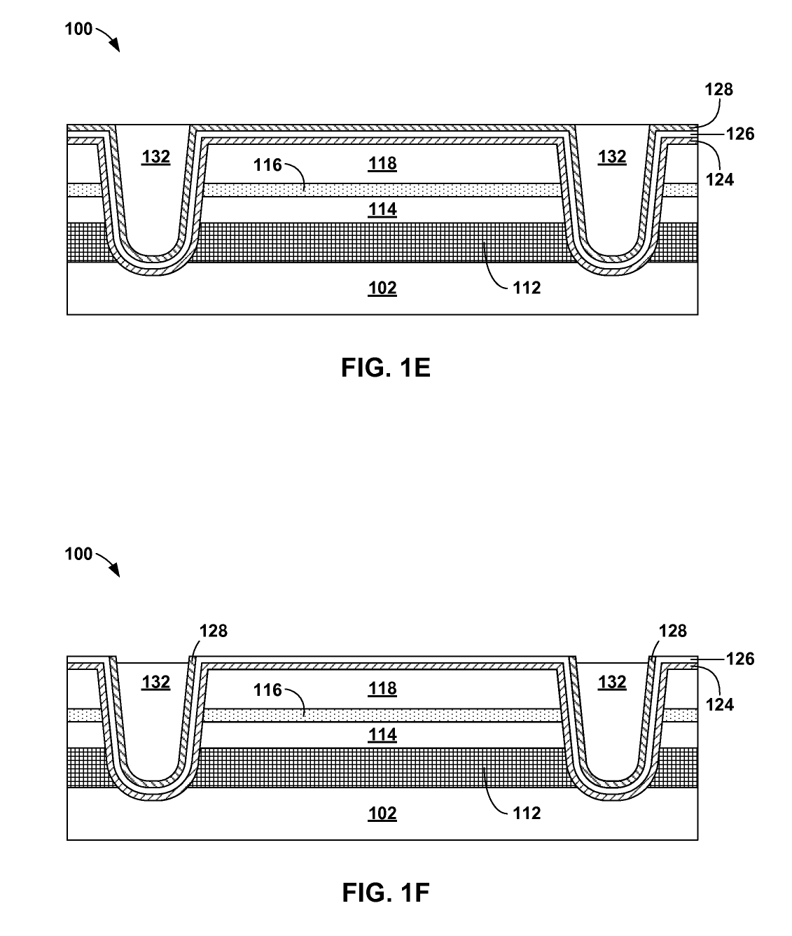

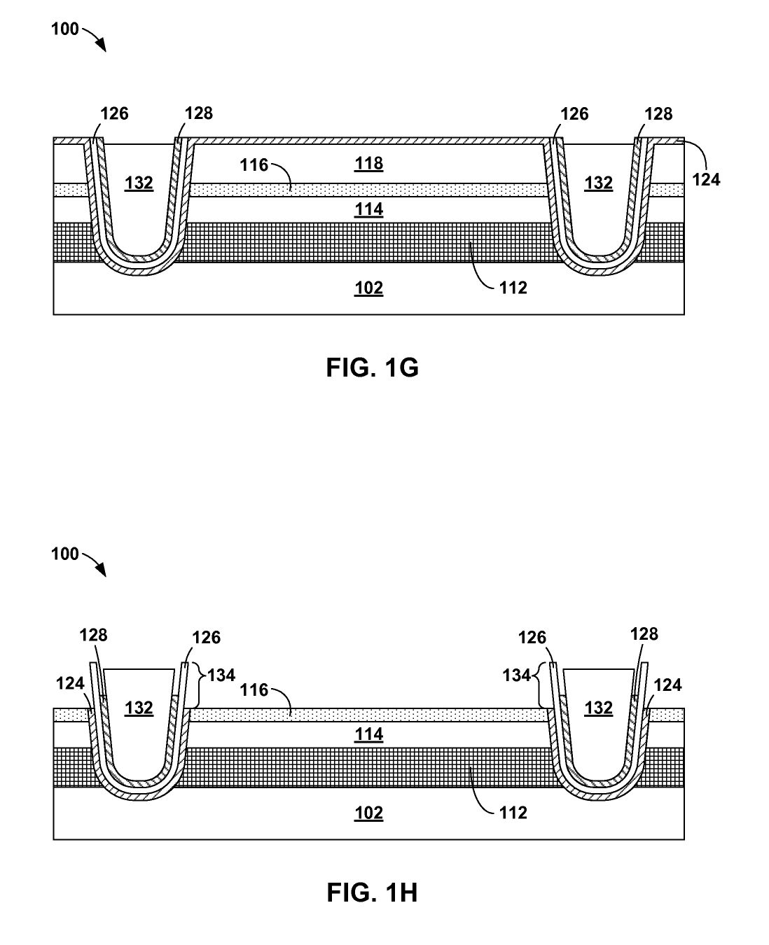

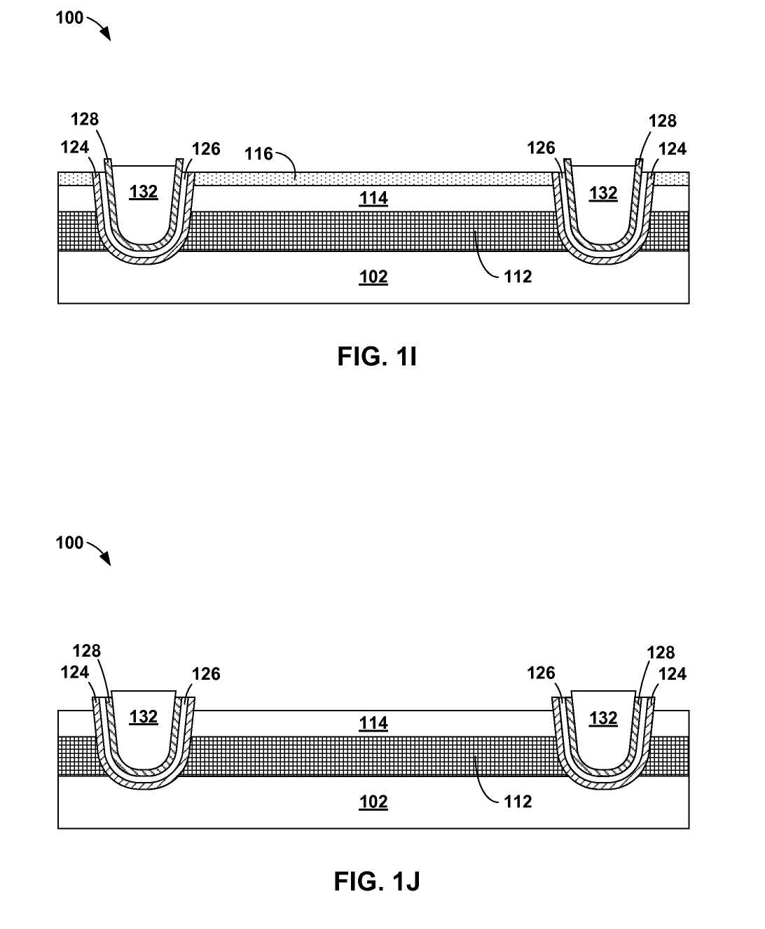

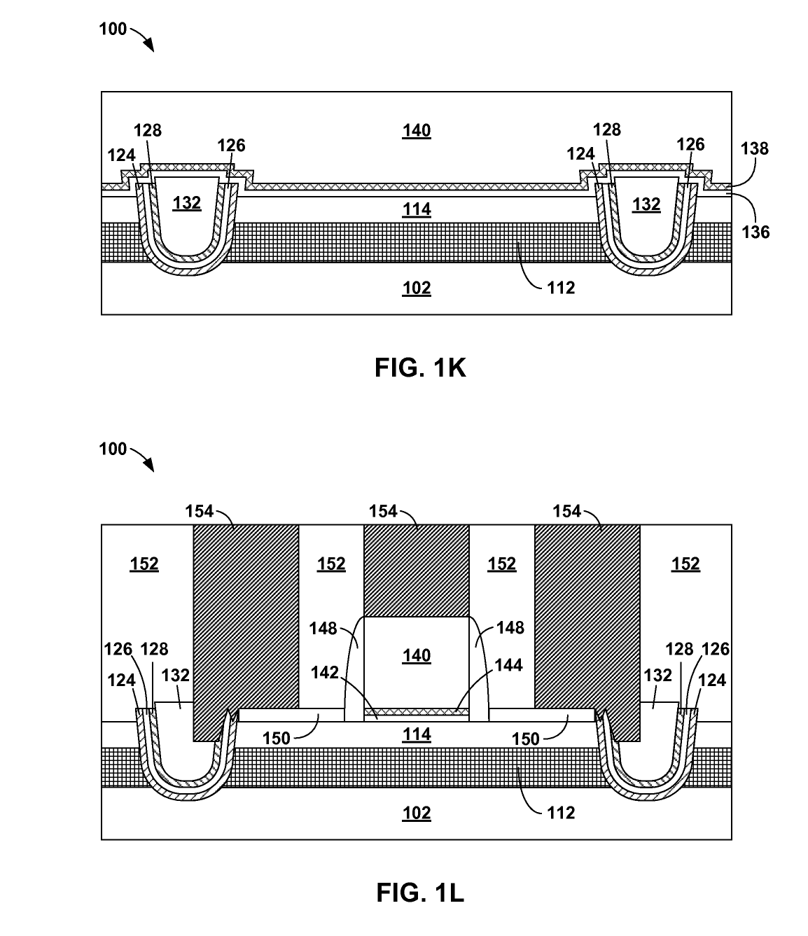

Referring now to FIGS. 1A-1L, exemplary process steps of forming an isolation structure 100 for a semiconductor device are shown. Specifically a shallow trench may be formed in an SOI substrate. Using standard processes, a stack of liners may be deposited within the shallow trench followed by the deposition of a shallow trench fill portion. A chemical mechanical polishing (CMP) technique may be used to remove excess shallow trench fill portion from atop the SOI substrate. Next the stack of liners including a first nitride liner, a dielectric liner, and a second nitride liner may be partially removed. Finally, a gate dielectric layer, a work function metal layer, and a gate conductor may be deposited.

Referring now to FIG. 1A, a silicon-on-insulator (SOI) substrate 101 is shown. The SOI substrate 101 may include a base layer 102, a buried oxide (BOX) layer 104 formed on top of the base layer 102, and a SOI layer 106 formed on top of the BOX layer 104. The BOX layer 104 isolates the SOI layer 106 from the base layer 102. In one embodiment, the SOI substrate 101 may have a pad oxide layer 108 and a pad nitride layer 110 formed on a top surface of the SOI layer 106, where the pad nitride layer 110 may be located directly on top of the pad oxide layer 108. The base layer 102 may be made from any of several known semiconductor materials such as, for example, a bulk silicon substrate. Other non-limiting examples include silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the base layer 102 may be about, but is not limited to, several hundred microns thick. For example, the base layer 102 may include a thickness ranging from 0.5 mm to about 1.5 mm.

The BOX layer 104 may be formed from any of several dielectric materials. Non-limiting examples include, for example, oxides, nitrides and oxynitrides of silicon. The BOX layer 104 may also include oxides, nitrides and oxynitrides of elements other than silicon. In addition, the BOX layer 104 may include crystalline or non-crystalline dielectric material. Moreover, the BOX layer 104 may be formed using any of several methods. Non-limiting examples include ion implantation methods, thermal or plasma oxidation or nitridation methods, chemical vapor deposition methods and physical vapor deposition methods. The BOX layer 104 may include a thickness ranging from about 5 nm to about 200 nm. In one embodiment, the BOX layer 104 may be about 25 nm thick.

The SOI layer 106 may include any of the several semiconductor materials included in the base layer 102. In general, the base layer 102 and the SOI layer 106 may include either identical or different semiconducting materials with respect to chemical composition, dopant concentration and crystallographic orientation. In one embodiment, the base layer 102 and the SOI layer 106 include semiconducting materials that include at least different crystallographic orientations. Typically the base layer 102 or the SOI layer 106 include a {110} crystallographic orientation and the other of the base layer 102 or the SOI layer 106 includes a {100} crystallographic orientation. Typically, the SOI layer 106 includes a thickness ranging from about 5 nm to about 100 nm. Methods for making the SOI layer 106 are well known in the art. Non-limiting examples include SIMOX (Separation by Implantation of OXygen), wafer bonding, and ELTRAN® (Epitaxial Layer TRANsfer).

The pad oxide layer 108 may include a silicon oxide or a silicon oxynitride. In one embodiment, the pad oxide layer 108 can be formed, for example, by thermal or plasma conversion of a top surface of the SOI layer 106 into a dielectric material such as silicon oxide or silicon oxynitride. In one embodiment, the pad oxide layer 108 can be formed by deposition of silicon oxide or silicon oxynitride by chemical vapor deposition (CVD) or atomic layer deposition (ALD). The pad oxide layer 108 may have a thickness ranging from about 1 nm to about 10 nm, although a thickness less than 1 nm and greater than 10 nm may be acceptable. In one embodiment, the pad oxide layer 108 may be about 5 nm thick.

The pad nitride layer 110 may include an insulating material such as, for example, silicon nitride. The pad nitride layer 110 may be formed using conventional deposition methods, for example, low-pressure chemical vapor deposition (LPCVD). In one embodiment, the pad nitride layer 110 may have a thickness ranging from about 5 nm to about 100 nm. In one particular embodiment, the pad nitride layer 110 may be about 50 nm thick.

In one embodiment, the SOI substrate 101 can be an ultra-thin semiconductor-on-insulator (UTSOI) substrate. The top SOI layer (e.g. 106) of a typical UTSOI substrate may also be referred to as an ultra-thin semiconductor-on-insulator (UTSOI) layer, and have a thickness ranging from about 3 nm to about 15 nm. The BOX layer (e.g. 104) beneath the UTSOI of a UTSOI substrate can have a thickness ranging from about 10 nm to about 50 nm.

Referring now to FIG. 1B, a cell location is identified and a mask layer 120 of a suitable masking material may be deposited on a top surface of the pad nitride layer 110 (shown in FIG. 1A) and patterned using a conventional photolithographic techniques. The mask layer 120 may include suitable masking materials such as, for example, photoresist or hardmask such as silicon dioxide. A shallow trench 122 is formed by etching through the pad nitride layer 110 (shown in FIG. 1A), the pad oxide 108 (shown in FIG. 1A), the SOI layer 106 (shown in FIG. 1A), and an upper portion 111 of the base layer 102 as illustrated by the figure. The shallow trench 122 extends vertically from the top surface of the pad nitride layer 110 (shown in FIG. 1A) to a depth below the interface between the base layer 102 and the BOX layer 104 (shown in FIG. 1A). The shallow trench 122 may be formed using, for example, an anisotropic dry etching technique, such as reactive ion etching (RIE). The shallow trench 122 laterally surrounds a vertical stack, from bottom to top, the upper portion 111 of the base layer 102, a BOX layer region 112, a SOI layer region 114, a pad oxide layer region 116, and a pad nitride layer region 118.

Referring now to FIG. 1C, a stack of liners may be deposited on top of the pad nitride layer region 118 and within the shallow trench 122 (shown in FIG. 1B). A first nitride liner 124 may be deposited first, as shown in the figure. In one embodiment, the first nitride liner 124 may include silicon nitride. The first nitride liner 124 may be deposited as a contiguous layer on the entirety of the physically exposed surfaces of the base layer 102, the BOX layer region 112, the SOI layer region 114, the pad oxide layer region 116, and the pad nitride layer region 118. The first nitride liner 124 may be deposited, for example, by chemical vapor deposition (CVD), molecular layer deposition (MLD), or a combination thereof. The first nitride liner 124 can be stoichiometric (i.e., have a composition of Si₃N₄) or non-stoichiometric. The first nitride liner 124 may range in thickness from about 1 nm to about 10 nm, although a thickness less than 1 nm and greater than 10 nm may be acceptable.

Next, a dielectric liner 126 may be deposited on top of the first nitride liner 124, as shown in the FIG. 1C. The dielectric liner 126 may include a dielectric metal oxide material, i.e., a dielectric compound including at least one metal and oxygen. The dielectric metal oxide material can optionally include nitrogen, carbon, fluorine, chlorine, or some combination thereof. In one embodiment, the dielectric metal oxide material may include silicon. For example, the dielectric metal oxide material can be a material known in the art as high-k gate dielectric materials having a dielectric constant greater than the dielectric constant of silicon nitride, i.e., 7.9. Dielectric metal oxide materials may be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), and the like. The dielectric liner 126 may be deposited as a contiguous layer on top of the first nitride liner 124. Exemplary high-k dielectric materials include ZrO₂, La₂O₃, Al₂O₃, TiO₂, SrTiO₃, LaAlO₃, Y₂O₃. Other exemplary high-k materials may include HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x may independently range from 0.5 to 3 and each value of y may independently range from 0 to 2. Preferably, the dielectric liner 126 may include hafnium oxide or hafnium silicate. The dielectric liner 126 may range in thickness from about 1 nm to about 10 nm, although a thickness less than 1 nm and greater than 10 nm may be acceptable. Preferably, the dielectric liner 126 may range in thickness from about 3 nm to about 6 nm.

A second nitride liner 128 may be deposited on top of the dielectric liner 126 as shown in FIG. 1C. The second nitride liner 128 may be deposited as a contiguous layer on top of the dielectric liner 126. In one embodiment, the second nitride liner 128 may include silicon nitride. The second nitride liner 128 may be deposited, for example, by chemical vapor deposition (CVD), molecular layer deposition (MLD), or a combination thereof. The second nitride liner 128 can be stoichiometric (i.e., have a composition of Si₃N₄) or non-stoichiometric. The second nitride liner 128 may range in thickness from about 1 nm to about 10 nm, although a thickness less than 1 nm and greater than 10 nm may be acceptable. The dielectric liner 126 between the first nitride liner 124 and the second nitride liner 128 may be used to prevent a short circuit between a device subsequently formed on the SOI layer 106 and the base substrate 102.

Referring now to FIG. 1D, a shallow trench fill layer 130 may be deposited on top of the second nitride liner 128. The shallow trench fill layer 130 may be sequentially deposited after the deposition of the second nitride liner 128. In one embodiment, the shallow trench fill layer 130 may include silicon oxide. The shallow trench fill layer 130 may be deposited, for example, by chemical vapor deposition (CVD). The thickness (H₁) of the shallow trench fill layer 130 as measured from the top surface of the pad nitride layer region 118, may be greater than the depth (H₂) of the shallow trench 122, as measured between the topmost surface of the pad nitride layer region 118 and the bottommost surface of the shallow trench 122. The shallow trench fill layer 130 may fill the entirety of the shallow trench 122.

Referring now to FIG. 1E, a portion of the shallow trench fill layer 130 located above the horizontal plane of the topmost surface of the second nitride liner 128 may be removed, for example, by chemical mechanical planarization (CMP), a recess etch, or a combination thereof. A remaining portion of the shallow trench fill layer 130 after planarization includes a shallow trench fill portion 132. The shallow trench fill portion 132 contiguously and laterally surrounds the vertical stack of the upper portion of the base layer 102, the BOX layer region 112, the SOI layer region 114, the pad oxide layer region 116, and the pad nitride layer region 118. The shallow trench fill portion 132 is laterally spaced from the vertical stack of the upper portion 111 (shown in FIG. 1B) of the base layer 102, the BOX layer region 112, the SOI layer region 114, the pad oxide layer region 116, and the pad nitride layer region 118 by substantially vertical portions of the first nitride liner 124, the dielectric liner 126, and the second nitride liner 128. The shallow trench fill portion 132 fills the shallow trench 122 (shown in FIG. 1B).

Referring now to FIG. 1F, a portion of the second nitride liner 128 may be removed from above the dielectric liner 126. In one embodiment, the portion of the second nitride liner 128 may be removed, for example, by a wet etching technique using hot phosphoric acid or by a dry etching technique. The shallow trench portion 132 may not be affected during the removal of the portion of the second nitride liner 128 because the etching technique used can be very selective to oxide, or the material of the shallow trench fill portion 132.

In an additional process step the shallow trench fill portion 132 may be recessed with an etching technique using different etching chemistries than that used for the removal of the portion of the second nitride liner 128. In one embodiment, the shallow trench fill portion 132 may be recessed, for example, by a wet etching technique or by a dry etching technique.

Referring now to FIG. 1G, a portion of the dielectric liner 126 located directly above the first nitride liner 124 may be removed. In one embodiment, the portion of the dielectric liner 126 may be removed, for example, by a wet etching technique or by a dry etching technique. The chemistry for etching the dielectric liner 126 depends on the composition of the dielectric liner 126. Any chemistry for etching the dielectric liner 126 as known in the art can be used. For example, a chlorine based dry etching technique may be used to remove a hafnium oxide dielectric liner. Depending on the etching technique used the shallow trench fill portion 132 may be further recessed during the removal of the dielectric liner 126.

Referring now to FIG. 1H, a portion of the first nitride liner 124 located directly above the pad nitride layer region 118 may be removed. In one embodiment, the portion of the first nitride liner 124 may be removed, for example, by a wet etching technique using hot phosphoric acid or by a dry etching technique.

With continued reference to FIG. 1H, the pad nitride layer region 118 may be removed. The pad nitride layer region 118 may be removed for example, by a wet etching technique or a dry etching technique. In one embodiment, the pad nitride layer region 118 may include silicon nitride, and a wet etching technique using hot phosphoric acid may be used to remove the pad nitride layer region 118. After removal of the portion of the first nitride liner 124, the portion of the dielectric liner 126, the portion of the second nitride liner 128, and the pad nitride layer region 118 a small portion 134 of the dielectric liner 126 may remain extending above the top surface of the pad oxide layer region 116, as shown in FIG. 1H.

Referring now to FIG. 1I, the small portion 134 (shown in FIG. 1H) of the dielectric liner 126 may be recessed to a level equal with a top surface of the first nitride liner 124. In one embodiment, the small portion 134 (shown in FIG. 1H) of the dielectric liner 126 may be recessed, for example, by using a wet etching technique having a chemistry capable of recessing the small portion 134 (shown in FIG. 1H) of the dielectric liner 126 selective to the first nitride liner 124, the second nitride liner 128, and the pad oxide layer region 116. In one embodiment, the etch chemistry may be selective to silicon oxide. In one embodiment, a chlorine based dry etching technique may be used to recess the small portion 134 (shown in FIG. 1H) of the dielectric liner 126. Because the chlorine based etching technique is relatively selective to oxide the shallow trench fill portion 132 may not be further recessed during the removal of the small portion 134 of the dielectric liner 126, however, some recess is acceptable.

In one embodiment, the top portion of the shallow trench fill portion 132 may be recessed during the removal of the pad oxide layer region 116 or in a different recess etching step so that the top surface of the shallow trench fill portion 132 becomes substantially coplanar with the top surface of the first nitride liner 124, the dielectric liner 126, and the second nitride liner 128. As used herein, a first surface is substantially coplanar with a second surface if the difference in height between the first surface and the second surface is limited by inherent limitations of processing techniques intended to make the first and second surfaces coplanar. It should be noted that the difference in height depicted in the figures may be exaggerated and is merely a pictorial representation.

Referring now to FIG. 1J, the pad oxide layer region 116 (shown in FIG. 1I) may be removed. In one embodiment, a wet etching technique using hydrofluoric acid may be used to remove the pad oxide layer region 116. The second nitride liner 128 may further be recessed below the top surface of the shallow trench fill portion 132 during the removal of the pad oxide layer region 116. After removing the pad oxide layer region 116 the top surfaces of the first nitride liner 124, the dielectric liner 126, and the second nitride liner 128 may be substantially flush with one another, and below the top surface of the shallow trench fill portion 132.

Referring now to FIG. 1K, a semiconductor device may be formed on top of the isolation structure 100. The semiconductor device can include, for example, a field effect transistor, a junction transistor, a diode, a resistor, a capacitor, an inductor, an optical device, or any other semiconductor device known in the art. In one embodiment, the semiconductor device may include a field effect transistor. In such embodiments, a gate dielectric layer 136 may be deposited by a conformal deposition process such as chemical vapor deposition (CVD) or atomic layer deposition (ALD). The gate dielectric layer 136 may be contiguously deposited on top of the shallow trench fill portion 132, the first nitride liner 124, the dielectric liner 126, the second nitride liner 128, and the SOI layer region 114. The gate dielectric layer 136 may include any gate dielectric material known in the art including, but not limited to, silicon-oxide-based gate dielectric materials and dielectric metal oxide materials. If a dielectric metal oxide material is used as the entirety of, or as a part of, the gate dielectric layer 136, the dielectric metal oxide material within the gate dielectric layer 136 may have the same composition as, or a different composition from, the dielectric metal oxide material of the dielectric liner 126. Further, the dielectric metal oxide material within the gate dielectric layer 136 may have the same thickness as, or a different thickness from, the dielectric metal oxide material of the dielectric liner 126.

With continued reference to FIG. 1K, a work function metal layer 138 and a gate material layer 140 may be conformably deposited on top of the gate dielectric layer 136. The work function metal layer 138 and the gate material layer 140 may be subsequently patterned to form the semiconductor device gate stack. In one embodiment, the work function metal layer 138 may include, for example, TiN, Ta, or TaC and the gate material layer 140 may include, for example, polysilicon, tungsten, or aluminum.

Referring to FIG. 1L, the gate stack, pattered using conventional photolithography techniques, is shown. The gate stack may include a gate oxide 142 (made from the gate dielectric layer 136), a work function metal 144 (made form the work function metal layer 138), and a gate conductor 146 (made from the gate material layer 140). A pair of dielectric spacers 148 may be formed using conventional photolithography techniques on opposite sides of the gate stack as shown in the figure. A pair of raised source/drain regions 150 may be formed by selective epitaxial Si growth. The pair of raised source/drain regions 150 may be either n-doped or p-doped. Typically, n-doped source/drain regions are used for forming p-channel field effect transistors (p-FETs), and p-doped source/drain regions are used for forming n-channel field effect transistors (n-FETs). However, the source/drain regions of one device on a semiconductor substrate may be n-doped while the source/drain regions of another device on the same semiconductor substrate may be p-doped.

An inter-layer dielectric (ILD) layer 152 may be deposited on top of the isolation structure 100 using conventional deposition techniques known in the art. One or more contact via holes may be etched through the ILD 152 and then filled with a conductive material to form a device contact 154. The device contact 154 may be use to make electrical connections to the semiconductor device, and more specifically the gate conductor 146, and the pair of source/drain regions 150.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

What is claimed is:

1. A method comprising:
etching a shallow trench laterally surrounding a portion of a semiconductor substrate, the semiconductor substrate comprising a semiconductor-on-insulator SOI layer, a pad oxide layer, and a pad nitride layer;
depositing a first nitride liner, a dielectric liner, and a second nitride liner in the shallow trench, wherein the dielectric liner is located between the first and the second nitride liner; and
filling the shallow trench with a shallow trench fill portion.

2. The method of claim 1, further comprising:
recessing the shallow trench fill portion, the first nitride liner, the dielectric liner, the second dielectric liner, the pad oxide layer, and the pad nitride layer such that the SOI layer is substantially coplanar with the shallow trench fill portion, and
forming a semiconductor device.

3. The method of claim 2; wherein the semiconductor device comprises a gate stack on top of the SOI layer, dielectric spacers disposed on opposite sides of the gate stack, a raised source, a raised drain, and a device contact, wherein the device contact is in electrical connection with the raised source or the raised drain.

4. The method of claim 3, wherein the gate stack comprises a gate conductor positioned on top of a gate oxide, and a work function metal positioned between the gate oxide and the gate conductor.

5. The method of claim 1, wherein the depositing the first nitride liner step and the depositing the second nitride liner step comprises depositing a material having a thickness ranging from about 1 nm to 10 nm.

6. The method of claim 1, wherein the depositing the first nitride liner step and the depositing the second nitride liner step comprises depositing silicon nitride.

7. The method of claim 1, wherein the depositing the dielectric liner step comprises depositing a material having a thickness ranging from about 1 nm to 10 nm.

8. The method of claim 1, wherein the depositing the dielectric liner step comprises depositing hafnium oxide.

9. The method of claim 1, wherein the depositing the dielectric liner step comprises depositing hafnium silicate.

10. The method of claim 1, wherein the dielectric liner comprises a material selected from the group consisting of: ZrO₂, La₂O₃, Al₂O₃, TiO₂, SrTiO₃, LaAlO₃, Y₂O₃.

11. The method of claim 1, wherein the dielectric liner comprises a material selected from the group consisting of: HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof, wherein the value of x may range from about 0.5 to 3, and the value of y may range form about 0 to 2.

12. The method of claim 1, wherein the dielectric liner comprises a material having a dielectric constant greater than 8.

13. The method of claim 1, wherein the filling the shallow trench step comprises depositing silicon oxide using a chemical vapor deposition technique.

14. A structure comprising:
a shallow trench laterally surrounding a portion of a semiconductor substrate, the semiconductor substrate comprising a semiconductor-on-insulator SOI layer, a pad oxide layer, and a pad nitride layer;
a first nitride liner, a dielectric liner, and a second nitride liner located adjacent to a sidewall and a bottom of the shallow trench, wherein the dielectric liner is located between the first and the second nitride liner; and
a shallow trench fill portion configured on top of the second nitride liner.

15. The structure of claim 14, further comprising:
forming a semiconductor device on top of the SOI layer, wherein the semiconductor device comprises a gate stack on top of the SOI layer, a pair of dielectric spacers located on opposite sides of the gate stack, a raised source region, a raised drain region, and a device contact, and wherein the device contact is in electrical connection with the raised source or the raised drain.

16. The structure of claim 15, wherein the gate stack comprises a gate conductor positioned on top of a gate oxide, and a work function metal positioned between the gate oxide and the gate conductor.

17. The structure of claim 14, wherein the first and second nitride liner comprises a material having a thickness ranging from about 1 nm to 10 nm.

18. The structure of claim 14, wherein the first and second nitride liner comprises silicon nitride.

19. The structure of claim 14, wherein the dielectric liner comprises a material having a thickness ranging from about 1 nm to 10 nm.

20. The structure of claim 14, wherein the dielectric liner comprises hafnium oxide

21. The structure of claim 14, wherein the dielectric liner comprises hafnium silicate.

22. The structure of claim 14, wherein the dielectric liner comprises a material selected from the group consisting of: ZrO₂, La₂O₃, Al₂O₃, TiO₂, SrTiO₃, LaAlO₃, Y₂O₃.

23. The structure of claim 14, wherein the dielectric liner comprises a material selected from the group consisting of: HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof, wherein the value of x may range from about 0.5 to 3, and the value of y may range form about 0 to 2.

24. The structure of claim 14, wherein the dielectric liner comprises a material having a dielectric constant greater than 8.

25. The structure of claim 14, wherein the shallow trench fill portion comprises silicon oxide.
